(19) United States
(12) Patent Application Publication
(10) Pub. No.: US 2014/0078679 A1
(43) Pub. Date: Mar. 20, 2014

(54) ELECTRONIC DEVICE

(71) Applicant: FUJITSU LIMITED, Kawasaki-shi (JP)

(72) Inventors: Yosuke TSUNODA, Tachikawa (JP); Jie WEI, Hachioji (JP); Masumi SUZUKI, Kawasaki (JP); Michimasa AOKI, Kawasaki (JP); Wataru NISHIYAMA, Kawasaki (JP)

(73) Assignee: FUJITSU LIMITED, Kawasaki-shi (JP)

(21) Appl. No.: 13/956,540

(22) Filed: Aug. 1, 2013

(30) Foreign Application Priority Data
Sep. 18, 2012 (JP) 2012-204832

(51) Int. Cl. H05K 7/20

(52) U.S. Cl. CPC H05K 7/2039
USPC 361/720; 174/252

(57) ABSTRACT

An electronic device includes: a resin plate; an electronic component disposed on one side of the resin plate in a thickness direction; and a heat transfer member having higher heat conductivity than the resin plate, the heat transfer member transferring heat from the one side to the other side of the resin plate in the thickness direction.

### CROSS-REFERENCE TO RELATED APPLICATION

This application is based upon and claims the benefit of priority of the prior Japanese Patent Application No. 2012-204832, filed on Sep. 18, 2012, the entire contents of which are incorporated herein by reference.

### FIELD

The embodiments discussed herein are related to electronic devices.

### BACKGROUND

It is desirable that electronic devices, such as portable terminals, radiate heat generated by heat generating components assembled therein. For example, in a known technique, a metal rod penetrating through a printed-circuit board is fixed to a metal chassis, and an elastic heat-conducting insulating member is disposed between the metal rod and a heat-generating electronic component to transfer heat generated by the heat-generating electronic component to the metal chassis via the metal rod.

Japanese Laid-open Utility Model No. 3-1489 is an example of related art.

Some electronic devices have a resin plate therein. Because the resin plate has lower heat conductivity than a metal member, the resin plate often inhibits heat transfer.

### SUMMARY

According to an aspect of the invention, an electronic device includes: a resin plate; an electronic component disposed on one side of the resin plate in a thickness direction; and a heat transfer member having higher heat conductivity than the resin plate, the heat transfer member transferring heat from the one side to the other side of the resin plate in the thickness direction.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a longitudinal sectional view of a smart phone according to a first embodiment;

FIG. 2 is a longitudinal sectional view of the smart phone according to the first embodiment, in which a back cover member is detached from a casing;

FIG. 3 is an enlarged sectional view of a heat-conducting member and its vicinity of the smart phone according to the first embodiment;

FIG. 4 is a perspective view of the heat-conducting member of the smart phone according to the first embodiment;

FIG. 5 is an enlarged sectional view of a heat-conducting member and its vicinity of a smart phone according to a second embodiment;

FIG. 6 is a perspective view of the heat-conducting member of the smart phone according to the second embodiment; and

FIG. 7 is a perspective view of a heat-conducting member of a smart phone according to a third embodiment.

### DESCRIPTION OF EMBODIMENTS

Detailed description of a first embodiment will be given below with reference to the drawings.

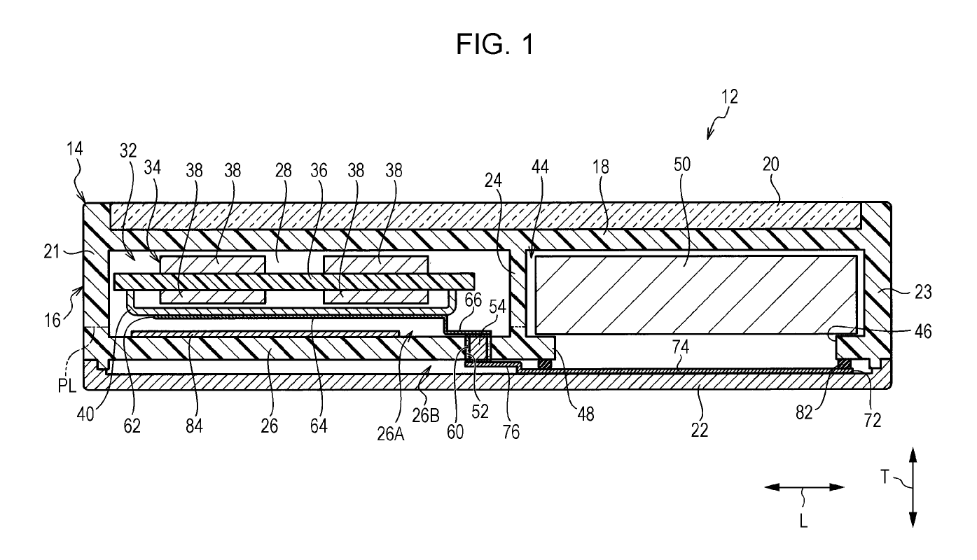

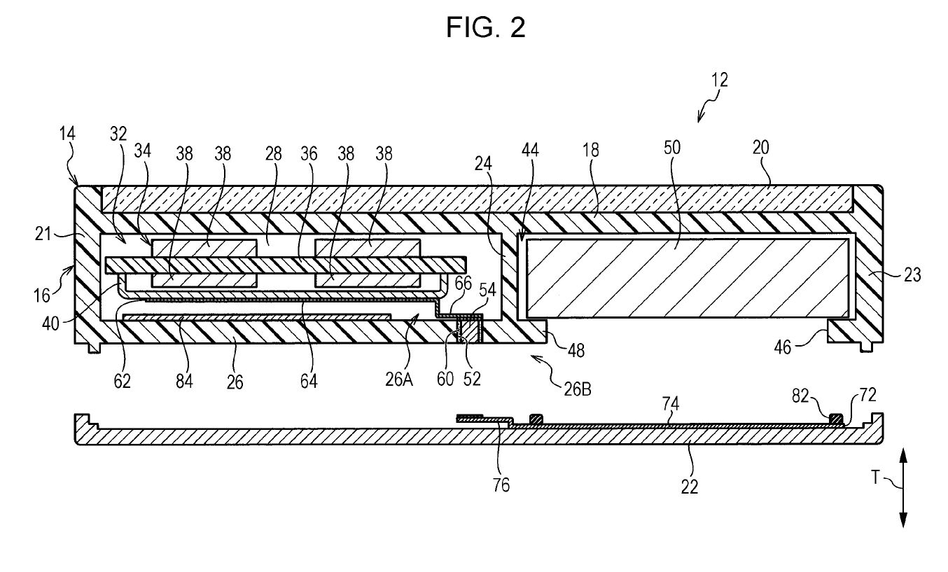

As illustrated in FIGS. 1 and 2, in the first embodiment, a multi-functional mobile phone 12 (hereinbelow, a “smart phone”), which is an example of a portable electronic device, is taken as an example of an electronic device. In the drawings, longitudinal, width, and thickness directions of the smart phone 12 are indicated by arrows L, W, and T, respectively. In FIGS. 1 and 2, the left side corresponds to the upper side of the smart phone 12.

The smart phone 12 according to this embodiment has a resin case 14. The case 14 has a rectangular shallow frame 16 defining the outer shape of the smart phone 12. The frame 16 includes an upper plate 21 and a lower plate 23 positioned at the upper part and lower part in the longitudinal direction, and side walls 28 positioned at both ends in the width direction. In FIGS. 1 and 2, only the side wall 28 on the far side is illustrated.

One side (in FIGS. 1 and 2, the upper side) of the frame 16 in the thickness direction is closed by a front cover plate 18. A touch screen 20, which also serves as an information display, is provided on the outer side of the front cover plate 18 in the thickness direction. The touch screen 20 is an example of a display screen. Instead of (or in addition to) the touch screen 20, an information display, an operation panel for allowing a user to input a command, and/or an operation button may be provided.

The other side (in FIGS. 1 and 2, the lower side) of the frame 16 in the thickness direction is covered by a back cover member 22 having a plate shape. Although the material of the back cover member 22 is not specifically limited, the back cover member 22 according to this embodiment is made of resin. In this embodiment, the back cover member 22 covers a resin plate 26 (described below). The back cover member 22 is normally engaged with the frame 16 with an engaging member or the like, but the back cover member 22 may be detached from the frame 16 by releasing the engagement of the engaging member.

Furthermore, in the example illustrated in FIGS. 1 and 2, portions of the case 14 are exposed outside to serve as the outer surface of the smart phone 12. However, a cover member or the like may be provided on the outside of the case 14.

A partition wall 24 is provided inside the frame 16, substantially in the middle thereof in the longitudinal direction. The resin plate 26 is provided above (in FIGS. 1 and 2, below) the partition wall 24. The resin plate 26 extends in both top-bottom and width directions of the casing 16. Hereinbelow, the upper side of the resin plate 26 in FIG. 1 is referred to as a one side 26A in the thickness direction, and the lower side of the resin plate 26 in FIG. 1 is referred to as the other side 26B in the thickness direction.

A portion surrounded by the substantially upper half portions of the two side plates 28 of the case 14, the substantially upper half portion of the front cover plate 18, the upper plate 21, the partition wall 24, and the resin plate 26 is an enclosed space 32 having a rectangular parallelepiped shape. In actuality, the actual case 14 is formed of two (or more) components divided at a parting line PL (two-dot chain line) in FIG. 1. By joining the components at the parting line PL, the enclosed space 32 is produced in the case 14.

The enclosed space 32 accommodates an electronic unit 34. The electronic unit 34 includes a substrate 36. The substrate 36 has a plurality of electronic components 38 mounted thereto and a predetermined circuit pattern formed thereon. In this embodiment, the substrate 36 is disposed inside the enclosed space 32 so as to be parallel to the front cover plate 18 and is fixed to the case 14 with fasteners (for example, pins or bolts).

A shielding member 40 is attached to a surface of the substrate 36 facing the resin plate 26. In this embodiment, the shielding member 40 is formed of metal, into a plate shape. The shielding member 40 is provided so that an antenna member 84 (described below) and the electronic components 38 on the substrate 36 do not electromagnetically affect each other.

A space surrounded by the lower plate 23 of the frame 16, the partition wall 24, and the substantially lower half portion of the front cover plate 18 is a battery storage portion 44 in which a battery 50 is accommodated. The battery storage portion 44 is an example of a component storage portion, and the battery 50 is an example of a storage component.

The case 14 has an insertion hole 46 through which the battery may be inserted into the battery storage portion 44. The insertion hole 46 is an example of a storage hole. Note that pawls 48 extend from the resin plate 26 and the lower plate 23. The pawls 48 are partially engaged with the battery 50 stored in the battery storage portion 44 to inhibit unintentional falling off of the battery 50.

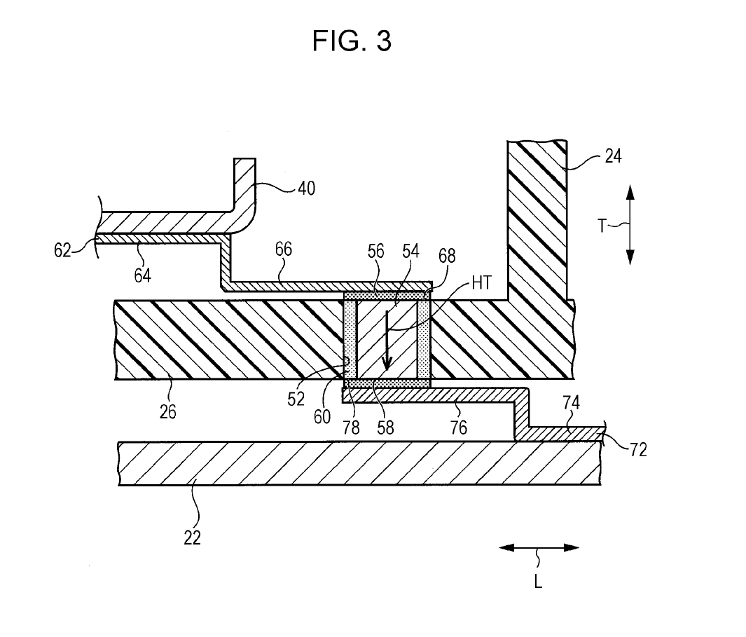

As illustrated in FIG. 3, the resin plate 26 has a through-hole 52 penetrating in the thickness direction. The through-hole 52 accommodates a heat-conducting member 54. The heat-conducting member 54 is formed of a material that has higher heat conductivity than the resin plate 26 (in this embodiment, metal).

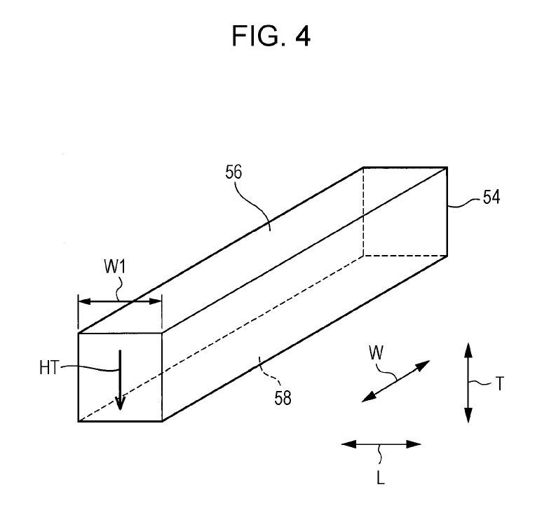

As illustrated in FIG. 4, the heat-conducting member 54 according to this embodiment is formed into a prism shape having rectangle end faces. The longitudinal direction of the heat-conducting member 54 corresponds to the width direction (indicated by the arrow W in FIG. 4) of the smart phone 12. The width, W1, of the heat-conducting member 54 (the length thereof in the longitudinal direction of the smart phone 12 (indicated by the arrow L)) is uniform from the inside to the outside of the enclosed space 32.

The top surface of the heat-conducting member 54 in FIGS. 3 and 4 serves as a heat-receiving surface 56, which is located inside the enclosed space 32. Furthermore, the bottom surface of the heat-conducting member 54 serves as a heat-releasing surface 58, which is located outside the enclosed space 32. The heat received by the heat-receiving surface 56 is transferred to the heat-releasing surface 58. In FIGS. 3 and 4, the direction of heat transfer is indicated by the arrow HT.

Although the shape of the heat-conducting member 54 depends on the shape of the through-hole 52, more specifically, the shape of the inner surface of the through-hole 52, the sectional shape of the heat-conducting member 54 (the sectional shape in the direction perpendicular to the longitudinal direction) is determined such that a predetermined clearance is left with respect to the inner surface of the through-hole 52.

The heat-receiving surface 56 of the heat-conducting member 54 is located on the same plane as the inner surface of the resin plate 26 (that is, the heat-receiving surface 56 of the heat-conducting member 54 and the inner surface of the resin plate 26 are flush with each other). Similarly, the heat-releasing surface 58 of the heat-conducting member 54 is located on the same plane as the outer surface of the resin plate 26.

A sealing member 60 is disposed between the heat-conducting member 54 and the inner circumferential surface of the through-hole 52. In this embodiment, the sealing member 60 is made of an elastic material (for example, silicone or rubber). The sealing member 60 is in tight contact with both the through-hole 52 and the heat-conducting member 54 to fill the clearance between them, thereby maintaining airtight condition of the enclosed space 32. Although the size of the clearance between the through-hole 52 and the heat-conducting member 54 may change due to temperature change because the coefficient of thermal expansion of the material of the case 14 (resin) is different from that of the material of the heat-conducting member 54 (metal), the sealing member 60 is able to respond to such change in size of the clearance and to maintain the airtight condition of the enclosed space 32.

The sealing member 60 is an example of an interposition member disposed between the heat-conducting member 54 and the inner circumferential surface of the through-hole 52. An elastic material, such as the above-described sealing member 60 (silicone or rubber), may be used as the interposition member. If the sealing member 60 is disposed between the heat-conducting member 54 and the inner circumferential surface of the through-hole 52, the sealing member 60 comes into contact with both the heat-conducting member 54 and the inner circumferential surface of the through-hole 52 when the size of the clearance between the through-hole 52 and the heat-conducting member 54 changes. Thus, the airtight condition of the enclosed space 32 is maintained.

A heat-receiving member 62 is disposed on one side 26A, in the thickness direction, of the resin plate 26 (in FIGS. 1 and 2, above the resin plate 26). The heat-receiving member 62 is formed of a material that has higher heat conductivity than the resin plate 26 (for example, metal), into a substantially plate shape.

As illustrated in FIG. 3, the heat-receiving member 62 according to this embodiment includes a heat-receiving portion 64 that is in surface-contact with the shielding member 40, and a heat-transfer portion 66 that is bent at an end of this heat-receiving portion 64 and is in contact with the heat-conducting member 54. In other words, the heat-receiving member 62 is an integrated component composed of a portion that is in contact with the shielding member 40 to receive heat generated by the electronic components 38 (that is, the heat-receiving portion 64) and a portion that transfers the heat to the heat-conducting member 54 (that is, the heat-transfer portion 66).

A heat-releasing member 72 is disposed on the other side 26B, in the thickness direction, of the resin plate 26 (in FIGS. 1 and 2, below the resin plate 26 and at a position where it covers the insertion hole 46). The heat-releasing member 72 is formed of a material that has higher heat conductivity than the resin plate 26 (for example, metal, which may be either the same as or different from the material of the heat-receiving member 62), into a substantially plate shape.

As illustrated in FIG. 3, the heat-releasing member 72 according to this embodiment includes a heat-releasing portion 74 that is in surface-contact with the back cover member 22 attached to the case 14, and a heat-transfer portion 76 that is bent at an end of the heat-releasing portion 74 and is in contact with the heat-conducting member 54. In other words, the heat-releasing member 72 is an integrated component composed of a portion that is in contact with the heat-conducting member 54 to receive heat from the heat-conducting member 54 (that is, the heat-transfer portion 76) and a portion that releases the heat to the outside (that is, the heat-releasing portion 74).

In particular, in this embodiment, the heat-releasing portion 74 is disposed on the other side 26B, in the thickness direction, of (in FIG. 1, below) the resin plate 26, on the opposite side (in FIG. 1, on the right side) of the heat-conducting member 54 from the heat-receiving portion 64 (heat-receiving member 62) in the direction in which the resin plate 26 extends. With this configuration, the heat-releasing portion 74 is disposed on the opposite side of the battery 50 from the touch screen 20. The heat-releasing portion 74 is in surface-contact with the back cover member 22 and is fixed thereto with an adhesive or the like. Therefore, as illustrated in FIG. 2, when the back cover member 22 is removed from the case 14, the heat-releasing member 72 integral with the back cover member 22 is also removed, and thus, the insertion hole 46 is opened.

The heat-transfer portion 66 of the heat-receiving member 62 is connected to the heat-receiving surface 56 (in FIGS. 1 to 3, the upper surface) of the heat-conducting member 54 with a heat-receiving-side elastic member 68 therebetween. Furthermore, the heat-transfer portion 76 of the heat-releasing member 72 is connected to the heat-releasing surface 58 (in FIGS. 1 to 3, the lower surface) of the heat-conducting member 54 with a heat-releasing-side elastic member 78 therebetween. The heat-receiving-side elastic member 68 and the heat-releasing-side elastic member 78 are both made of an elastic material having higher heat conductivity than the resin plate 26.

A gasket 82 is disposed between the heat-releasing portion 74 of the heat-releasing member 72 and the case 14. The gasket 82 has a closed shape surrounding the insertion hole 46 (for example, a rectangular frame shape). The gasket 82 fills the clearance between the case 14 and the heat-releasing portion 74 when the heat-releasing portion 74 is located at a predetermined position in the smart phone 12.

The antenna member 84 is attached to the surface of the resin plate 26 inside the enclosed space 32 (in FIGS. 1 and 2, the upper surface). The antenna member 84 is, for example, a transmitting and receiving antenna that enables the smart phone 12 and an external device to transmit or receive information in a non-contact manner.

In this embodiment, the heat-releasing member 72 is provided at a position where it is able to open or close the insertion hole 46 in the battery storage portion 44, not at a position between the resin plate 26 and the back cover member 22. Accordingly, the influence of the heat-releasing member 72 on transmitting/receiving of radio wave, performed by the antenna member 84, is reduced.

Next, advantages of the smart phone 12 according to this embodiment will be described.

In this smart phone 12, the through-hole 52 is provided in the resin plate 26, which defines the enclosed space 32, and the heat-conducting member 54 is accommodated in the through-hole 52. The heat received by the heat-receiving member 62 in the enclosed space 32 conducts to the heat-conducting member 54, and then the heat conducts from the heat-conducting member 54 to the heat-releasing member 72 on the outside of the enclosed space 32.

Accordingly, when the electronic components 38 in the smart phone 12 generate heat, a portion of the heat conducts through the shielding member 40, the heat-receiving member 62, the heat-conducting member 54, and the heat-releasing member 72 and is released outside the enclosed space 32. The smart phone 12, as a whole, is capable of radiating heat in the enclosed space 32 through the resin plate 26. Thus, it is possible to inhibit the electronic components 38, the case 14, the back cover member 22, the touch screen 20, etc., from being excessively heated.

In particular, in this embodiment, while the presence of the enclosed space 32 makes it easy to maintain high waterproof and dustproof properties of the enclosed space 32, it also encourages the heat to stay in the enclosed space 32. However, because the heat-conducting member 54 is accommodated in the through-hole 52 provided in the resin plate 26, even though the enclosed space 32 is provided, the heat in the enclosed space 32 may be effectively released.

Moreover, the heat-receiving member 62 is disposed on the one side 26A, in the thickness direction, of the resin plate 26 (inside the enclosed space 32). Hence, compared with a structure without the heat-receiving member 62, the heat generated by the electronic components 38 is efficiently received.

Furthermore, the heat-releasing member 72 is disposed on the other side 26B, in the thickness direction, of the resin plate 26 (outside the enclosed space 32). Hence, compared with a structure without the heat-releasing member 72, the heat conducting through the heat-conducting member 54 is efficiently released.

The heat-conducting member 54 is made of metal, whereas the resin plate 26 having the through-hole 52 is made of resin. Their coefficients of thermal expansion are different. Accordingly, when the heat conducts to the heat-conducting member 54 and the resin plate 26, the size of the clearance between the heat-conducting member 54 and the through-hole 52 changes. In this embodiment, the sealing member 60 made of an elastic material is disposed between the heat-conducting member 54 and the through-hole 52. Thus, even if the size of the clearance between the heat-conducting member 54 and the through-hole 52 changes, the sealing member 60 is elastically deformed to seal the clearance therebetween. That is, it is possible to maintain the enclosed space 32 sealed.

Furthermore, in this embodiment, the heat-receiving-side elastic member 68 is disposed between the heat-conducting member 54 and the heat-receiving member 62, and the heat-releasing-side elastic member 78 is disposed between the heat-conducting member 54 and the heat-releasing member 72. The heat-receiving-side elastic member 68 and the heat-releasing-side elastic member 78 are both elastic. Thus, the relative movement between the heat-conducting member 54 and the heat-receiving member 62 and the relative movement between the heat-conducting member 54 and the heat-releasing member 72 are absorbed by elastic deformation of the heat-receiving-side elastic member 68 and the heat-releasing-side elastic member 78. Furthermore, the heat-receiving-side elastic member 68 and the heat-releasing-side elastic member 78 have higher heat conductivity than the resin plate 26. Hence, for example, compared with a case where they are made of a material that has substantially the same heat conductivity as the resin plate 26, the heat transfer from the heat-receiving member 62 to the heat-conducting member 54 and the heat transfer from the heat-conducting member 54 to the heat-releasing member 72 are facilitated.

Next, a second embodiment will be described in detail with reference to the drawings. In the second embodiment, the overall structure of a smart phone, which is an example of an electronic device, is substantially the same as the smart phone 12 according to the first embodiment (see FIG. 1). Hence, the illustration thereof will be omitted. Furthermore, in the following description, components, members, etc. that are the same as those of the first embodiment will be denoted by the same reference numerals, and detailed descriptions thereof will be omitted.

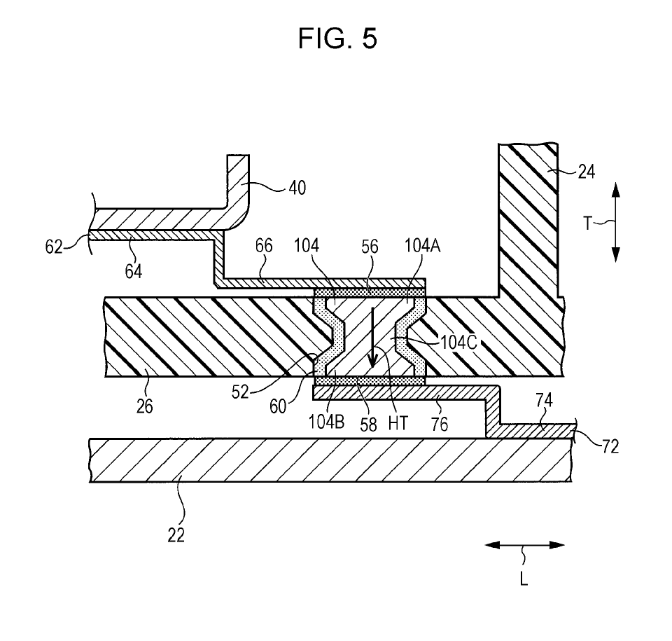

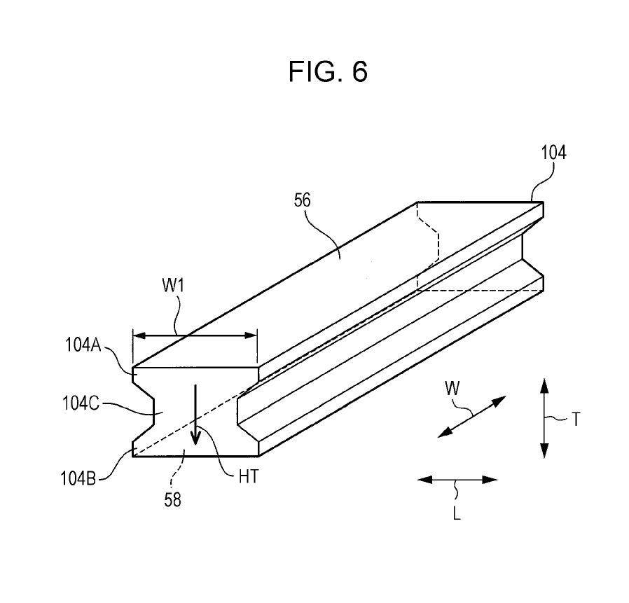

In the second embodiment, as illustrated in FIGS. 5 and 6, the sectional shape of the heat-conducting member is different from that according to the first embodiment. More specifically, a heat-conducting member 104 according to the second embodiment includes a heat-receiving-side part 104A, which is located on the upstream side in the direction of heat transfer (indicated by arrow HT), a heat-releasing-side part 104B, which is located on the downstream side in the direction of heat transfer, and a middle part 104C, which is located therebetween. The heat-receiving-side part 104A and the heat-releasing-side part 104B have larger sectional areas (the areas in the direction perpendicular to the direction of heat transfer) than the middle part 104C. More specifically, the width of the heat-receiving-side part 104A gradually increases from the boundary with the middle part 104C toward the heat-receiving surface 56, and the width of the heat-releasing-side part 104B gradually increases from the boundary with the middle part 104C toward the heat-releasing surface 58. The width of the middle part 104C is uniform and is smaller than the width of the heat-receiving surface 56 (heat-receiving-side part 104A) and the heat-releasing surface 58 (heat-releasing-side part 104B).

Because the area of the heat-receiving surface 56 is larger than the sectional area of the middle part 104C of the heat-conducting member 104 according to the second embodiment, heat is efficiently received compared with the structure in which the area of the heat-receiving surface 56 and the sectional area of the middle part 104C are the same.

Furthermore, because the area of the heat-releasing surface 58 is larger than the sectional area of the middle part 104C of the heat-conducting member 104 according to the second embodiment, heat is efficiently released compared with the structure in which the area of the heat-releasing surface 58 and the sectional area of the middle part 104C are the same.

As has been described, in the heat-conducting member 104 according to the second embodiment, the heat-receiving-side part 104A and the heat-releasing-side part 104B have a larger width than the middle part 104C, which is located therebetween in the direction of heat transfer. In the thickness direction of the resin plate 26, the heat-receiving-side part 104A and the heat-releasing-side part 104B are substantially engaged with the resin plate 26, forming an engaging portion. Thus, even if the heat-conducting member 104 is to be moved in the thickness direction of the resin plate 26, one of the heat-receiving-side part 104A and the heat-releasing-side part 104B is engaged with the inner surface of the through-hole 52, and the movement of the heat-conducting member 104 is avoided. Furthermore, unintentional falling off of the heat-conducting member 104 from the resin plate 26 is also avoided.

Other advantages of the smart phone according to the second embodiment are the same as the smart phone 12 according to the first embodiment.

By forming a projection or recess on the side surface of the heat-conducting member 54 according to the first embodiment to make it engageable with part of the resin plate 26, unintentional movement of the heat-conducting member 54 relative to the resin plate 26 and unintentional falling off of the heat-conducting member 54 from the resin plate 26 are avoided.

In the first and second embodiments, the method of producing the case 14 having the through-hole 52 accommodating the heat-conducting member 54 or the heat-conducting member 104 is not specifically limited. For example, in the first embodiment, the case 14 having the through-hole 52 and the heat-conducting member 54 with the sealing member 60 fitted thereto may be prepared, and the heat-conducting member 54 may be pressed into the through-hole 52 while elastically deforming the sealing member 60.

Furthermore, in the second embodiment, so-called “insert molding” may be employed. That is, the heat-conducting member 54 with the sealing member 60 fitted thereto is preliminarily placed in a mold for forming the case 14, and molten resin is poured into the mold to form the case 14. This insert molding may of course be used in the first embodiment to produce the case 14.

Next, a third embodiment will be described in detail with reference to the drawings. In the third embodiment too, the overall structure of a smart phone, which is an example of an electronic device, is substantially the same as the smart phone 12 according to the first embodiment (see FIG. 1). Hence, the illustration thereof will be omitted. Furthermore, in the following description, components, members, etc. that are the same as those of the first and second embodiments will be denoted by the same reference numerals, and detailed descriptions thereof will be omitted.

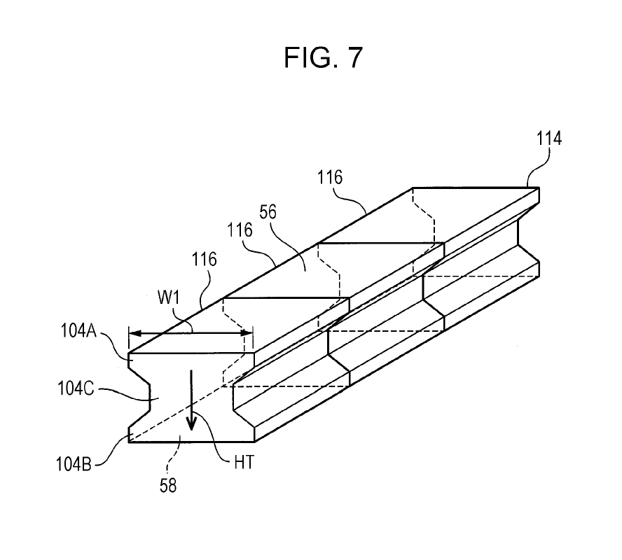

In the third embodiment, as illustrated in FIG. 7, the shape of the heat-conducting member is different from that of the second embodiment. That is, a heat-conducting member 114 according to the third embodiment includes a plurality of (in FIG. 7, three) heat transfer blocks 116 in the longitudinal direction (indicated by arrow W). These heat transfer blocks 116 are connected to form the heat-conducting member 114 having substantially the same shape as the heat-conducting member 104 according to the second embodiment.

Also in the third embodiment, the insert molding may be used to produce the case 14 having the through-hole 52 accommodating the heat-conducting member 114. In particular, in the third embodiment, because the heat-conducting member 114 is formed of a plurality of heat transfer blocks 116, positioning error of the heat transfer blocks 116 in the mold is reduced. That is, because positioning of the heat transfer blocks 116 in the mold is easy, the production of the case 14 is also easy.

The heat-conducting member 54 according to the first embodiment may also include a plurality of heat transfer blocks in the longitudinal direction.

In the above-described embodiments, the heat-receiving surface 56 of the heat-conducting member 54, 104, or 114 is flush with the inner surface (one surface) of the resin plate 26. It is also possible that, for example, the heat-receiving surface 56 is located below the inner surface of the resin plate 26 and inside the through-hole 52. In such a structure, however, because the heat-transfer portion 66 of the heat-receiving member 62 and the heat-receiving surface 56 of the heat-conducting member 54, 104, or 114 are distant, another heat transfer member has to be disposed therebetween, or the heat-transfer portion 66 has to be shaped such that it is in contact with the heat-receiving surface 56. In contrast, in the structure in which the heat-receiving surface 56 is flush with the inner surface of the resin plate 26, the heat-transfer portion 66 of the heat-receiving member 62, which has a flat shape, may be reliably kept in contact with the heat-receiving surface 56.

Similarly, because the heat-releasing surface 58 of the heat-conducting member 54, 104, or 114 is also flush with the outer surface (the other surface) of the resin plate 26, the heat-transfer portion 76 of the heat-releasing member 72, which has a flat shape, may be reliably kept in contact with the heat-releasing surface 58.

With either structure, by disposing the heat-receiving member 62 so as to face the electronic components 38, which generate heat, the heat-receiving member 62 may efficiently receive heat generated by the electronic components 38. By providing the heat-releasing member 72 on the opposite side of the resin plate 26 and the heat-conducting member 54 from the heat-receiving member 62, the heat-releasing member 72 may radiate heat to the opposite side to the heat-receiving member 62.

In the respective embodiments, examples in which the heat-releasing member 72 is in surface-contact with the back cover member 22 have been discussed. Because the heat-releasing member 72 is in contact with the back cover member 22 in this manner, the heat is directly transferred from the heat-releasing member 72 to the back cover member 22, and thus, more efficient heat release becomes possible.

Although the heat-releasing member 72 covers the insertion hole 46, through which the battery 50 is inserted, because the heat-releasing member 72 is attached to the back cover member 22, the insertion hole 46 is opened just by removing the back cover member 22 from the case 14, allowing the battery 50 to be inserted.

Moreover, as illustrated FIG. 1, the heat-releasing portion 74 of the heat-releasing member 72 is located on the opposite side of the battery 50 from the touch screen 20 with. Thus, the heat-releasing portion 74 does not affect the operability of the touch screen 20, or the touch screen 20 does not affect the heat-releasing performance of the heat-releasing portion 74.

The gasket 82 is disposed between the heat-releasing member 72 (heat-releasing portion 74) and the case 14 (around the insertion hole 46). The gasket 82 makes the battery storage portion 44 waterproof when the back cover member 22 is fitted to the case 14.

Furthermore, either one or both of the heat-receiving member and the heat-releasing member may be omitted. More specifically, as long as the heat-receiving surface of the heat-conducting member is located at a position where it reliably receives the heat generated by the electronic component, the heat-receiving member may be omitted. Similarly, if the heat-releasing surface of the heat-conducting member is located at a position where it reliably releases the heat, the heat-releasing member may be omitted.

Although the smart phone has been described as an example of the electronic device, the electronic device is not limited thereto. Small portable electronic devices, such as electronic dictionaries, notebook computers, tablet computers, and portable audio-visual players, sometimes employ a waterproof or dustproof structure in which electronic devices are disposed in an enclosed member. In such a structure, by disposing a heat-conducting member on a resin plate constituting a portion of the enclosed member, heat generated by electronic components may be radiated.

In addition, desktop computers, all-in-one computers, servers, and stationary audio-visual devices are also included in the electronic device. These electronic devices have larger casings than the above-mentioned small electronic devices and, because they do not have to have high waterproof or dustproof performance, sometimes the enclosed member is not provided therein. However, with a large resin plate, it is difficult to radiate heat generated by electronic components disposed on one side of the resin plate toward the other side of the resin plate in the thickness direction. In such a case, by providing a heat-conducting member on the resin plate, the heat generated by the electronic components may be efficiently radiated from one side toward the other side of the resin plate in the thickness direction.

Even in a structure without the enclosed member, the waterproof and dustproof properties may be obtained by adding a structure or member that achieves waterproof and dustproof properties to the electronic components.

In a structure without the enclosed member, the heat-conducting member does not have to be disposed in the through-hole provided in the resin plate. For example, the heat-conducting member may be continuous from one side to the other side of the resin plate in the thickness direction, so as to wrap around the edge of the resin plate.

Although some embodiments of the technique disclosed herein have been described above, the technique is not limited thereto. Other than the embodiments above, the technique may of course be variously modified and embodied within a scope not departing from the spirit thereof.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a resin plate;
an electronic component disposed on one side of the resin plate in a thickness direction; and
a heat transfer member having higher heat conductivity than the resin plate, the heat transfer member transferring heat from the one side to the other side of the resin plate in the thickness direction.

2. The electronic device according to claim 1,
wherein the heat transfer member includes:
a heat-conducting member continuous, in a direction of heat transfer, from the one side to the other side of the resin plate in the thickness direction;
a heat-receiving member that receives heat generated by the electronic component and transfers the heat to the heat-conducting member at the one side; and
a heat-releasing member that receives the heat from the heat-conducting member and releases the heat at the other side.

3. The electronic device according to claim 2, further comprising a heat-receiving-side elastic member that has heat conductivity and is disposed between the heat-conducting member and the heat-receiving member.

4. The electronic device according to claim 2, further comprising a heat-releasing-side elastic member that has heat conductivity and is disposed between the heat-conducting member and the heat-releasing member.

5. The electronic device according to claim 2,
wherein the heat-conducting member is disposed in a through-hole provided in the resin plate.

6. The electronic device according to claim 5, further comprising an elastic or viscous interposition member that is disposed between the heat-conducting member and an inner circumferential surface of the through-hole.

7. The electronic device according to claim 5,
wherein the heat-conducting member has an engaging portion that is engaged with the resin plate in a direction in which the through-hole is provided.

8. The electronic device according to claim 5,
wherein the heat-conducting member has a heat-receiving-member-side part located on the heat-receiving member side, a heat-releasing-member-side part located on the heat-releasing member side, and a middle part other than the heat-receiving-member-side part and the heat-releasing-member-side part, and
wherein at least one of the heat-receiving-member-side part and the heat-releasing-member-side part has a larger sectional area than the middle part in a direction perpendicular to the direction of heat transfer.

9. The electronic device according to claim 5,
wherein the heat-conducting member includes a plurality of heat transfer blocks in the direction perpendicular to the direction of heat transfer.

10. The electronic device according to claim 5, further comprising an enclosed member formed so as to include the resin plate,
wherein the heat transfer member is disposed in the through-hole provided in the resin plate.

11. The electronic device according to claim 2,
wherein the heat-receiving member is disposed so as to face a heat generating component, and
wherein the heat-releasing member is disposed on the opposite side of the heat-conducting member from the heat-receiving member in a direction in which the resin plate extends.

12. The electronic device according to claim 11, further comprising a component storage portion formed next to the enclosed member, the component storage portion having a storage hole through which a storage component is inserted or removed, the storage hole being opened or closed by the heat-releasing member.

13. The electronic device according to claim 12, further comprising:
a casing having the resin plate at a part thereof; and
a cover member that partially covers the casing,
wherein the heat-releasing member is in contact with the cover member.

14. The electronic device according to claim 13, further comprising a seal member provided between the heat-releasing member and the casing so as to surround the storage hole.

15. The electronic device according to claim 2,
wherein the heat-conducting member has a heat-receiving surface that is located on the same plane as one of the surfaces of the resin plate.

16. The electronic device according to claim 2,
wherein the heat-conducting member has a heat-releasing surface of that is located on the same plane as the other surface of the resin plate.

17. The electronic device according to claim 2, further comprising:
a battery; and
a display screen,
wherein the heat-releasing member is disposed on the opposite side of the battery from the display screen.
